(19) United States
(12) Patent Application Publication
(10) Pub. No.: US 2018/0254362 A1
(43) Pub. Date: Sep. 6, 2018

(54) MIXED TIN AND GERMANIUM PEROVSKITES

(71) Applicant: NUtech Ventures, Lincoln, NE (US)

(72) Inventors: Xiao Cheng Zeng, Lincoln, NE (US); Minggang Ju, Lincoln, NE (US); Nitin Padture, Providence, RI (US); Yuanyuan Zhou, Providence, RI (US); Min Chen, Providence, RI (US)

(73) Assignees: Brown University, Providence, RI (US); NUtech Ventures, Lincoln, NE (US)

(21) Appl. No.: 15/909,537

(22) Filed: Mar. 1, 2018

Related U.S. Application Data
(60) Provisional application No. 62/465,559, filed on Mar. 1, 2017.

(51) Int. Cl. H01L 31/032; H01L 51/42; H01L 31/04

(52) U.S. Cl. CPC H01L 31/032; C01P 2002/34; H01L 31/04; H01L 51/4213

(57) ABSTRACT

Perovskite materials useful in the manufacture of photovoltaic cells are provided. The perovskite materials have the formula AB′_{0.5}B″_{0.5}X₃ or A′_{0.5}A″_{0.5}B′_{0.5}B″_{0.5}X₃, wherein A, A′, and A″ are organic or inorganic cations, X is a halogen ion, B′ is tin, and B″ is germanium. Embodiments of the mixed tin and germanium halide perovskite materials possess a direct bandgap within the optimal range of 0.9-1.6 eV and have an optical absorption spectrum that is comparable to the state-of-the-art methylammonium lead iodide perovskites. The perovskite materials provided herein have been formulated to be lead-free.

This application is a nonprovisional application claiming the benefit of U.S. Provisional Patent Application Ser. No. 62/465,559, filed Mar. 1, 2017, the disclosure of which is incorporated herein by reference in its entirety.

### STATEMENT REGARDING FEDERALLY SPONSORED RESEARCH OR DEVELOPMENT

This invention was made with Government support under project numbers OIA-1538893/2611230129003 and DMR-1420645 by the National Science Foundation. The Government has certain rights in the invention.

### BACKGROUND

Inorganic-organic halide perovskites represent a major break-through in the development of highly efficient photovoltaic materials. Within only several years, polycrystalline thin-film perovskite photovoltaic (“PV”) devices have achieved power conversion efficiency (“PCE”) of 22.1%. The rapid rise in PCE, coupled with the prospect of low-cost precursors and facile synthesis, render the perovskite photovoltaic devices highly competitive for commercial applications.

However, there are obstacles yet to be overcome for outdoor applications. To date, most perovskites that give rise to high PCE still contain a toxic element—lead—including the popular methylammonium (“MA”) lead iodide (MAPbI₃) and formamidinium (“FA”) lead iodide (FAPbI₃). Moreover, most lead-containing perovskites tend to degrade in the presence of moisture, a challenging issue for long-term outdoor usage. For example, the photovoltaic devices based on the FAPbI₃ have shown PCE up to 20%; but the FAPbI₃ tends to transform from the black phase to yellow phase, resulting in dramatically reduced device efficiency.

Studies suggest that the fractional substitution of the organic cations MA with cesium (Cs) and FA can markedly enhance thermal stability of perovskites (sometimes called “hybrid perovskites” or “mixed perovskites”). The iodide can be also simultaneously replaced by other halides, e.g., chloride and bromide. Indeed, the mixed perovskites have led to several highly certified records in a chart published by the National Renewable Energy Laboratory (“NREL”). The mixing element strategy allows realization of tunable bandgaps for perovskites by changing the component ratio, such as FA/Cs or Cl/I ratios. This bandgap tunability is suitable for making certain photovoltaic cells (e.g., tandem photovoltaic cells).

### BRIEF SUMMARY

A perovskite material having the formula AB′_{0.5}B″_{0.5}X₃ is provided. In the formula, A is an organic or inorganic cation, X is a halogen ion, B′ is tin, and B″ is germanium. Additionally, a perovskite material having the formula A′_{0.5}A″_{0.5}B′_{0.5}B″_{0.5}X₃ is provided. In the formula, A′ is an inorganic cation and A″ is an organic cation, X is a halogen ion, B′ is tin, and B″ is germanium. Photovoltaic cells utilizing each of the foregoing perovskite materials are also provided.

### BRIEF DESCRIPTION OF THE FIGURES

FIG. 1A graphically illustrates Goldschmidt tolerance factors for certain perovskite materials.

FIG. 1B graphically illustrates computed PBE0 bandgaps for certain perovskite materials.

FIG. 2 illustrate computed PBE0 bandgap information of CsSnI₃ and FIG. 3 graphically illustrate computed bandgap CsSn_{0.5}Ge_{0.5}I₃ perovskite material using PBE0 functional with spin-orbit coupling.

FIGS. 4A-D graphically illustrate computed band structures (based on PBE0 functional) of CsSn_{0.5}Ge_{0.5}I₃, RbSn_{0.5}Ge_{0.5}I₃, MASn_{0.5}Ge_{0.5}I₃, and Rb_{0.5}FA_{0.5}Sn_{0.5}Ge_{0.5}I₃.

FIG. 5 illustrates predicted valence band maximum (“VBM”) and conduction band minimum (“CBM”) of perovskite materials CsSn_{0.5}Ge_{0.5}I₃ provided herein.

FIG. 6 is a table showing electronic effective masses of various perovskite materials provided herein.

FIG. 7 is a table showing exciton binding energies of various perovskite materials provided herein.

FIGS. 8A-D illustrate thermal stability of various perovskite materials using ab initio molecular dynamics (“AIMD”), with 8A depicting CsSn_{0.5}Ge_{0.5}I₃, 8B depicting RbSn_{0.5}Ge_{0.5}I₃, 8C depicting MASn_{0.5}Ge_{0.5}I₃, and 8D depicting Rb_{0.5}FA_{0.5}Sn_{0.5}Ge_{0.5}I₃.

FIG. 9 graphically illustrates decomposition enthalpy ΔH of different decomposition pathways for RbSn_{0.5}Ge_{0.5}I₃, MASn_{0.5}Ge_{0.5}I₃, and Rb_{0.5}FA_{0.5}Sn_{0.5}Ge_{0.5}I₃.

FIG. 10 graphically illustrates computed optical absorption spectra of certain perovskite materials provided herein.

FIG. 11 illustrates an example of a photovoltaic cell as provided herein. Note that the step appearance in the figure is shown merely to demonstrate the various layers of the photovoltaic cell and not to suggest that such step effect exists in the photovoltaic cell itself.

### DETAILED DESCRIPTION

A perovskite material having the formula AB′_{0.5}B″_{0.5}X₃ is provided. In the formula, A is an organic or inorganic cation, X is a halogen ion, B′ is tin, and B″ is germanium. A perovskite material having the formula A′_{0.5}A″_{0.5}B′_{0.5}B″_{0.5}X₃ is provided. In the formula, A′ is an inorganic cation and A″ is an organic cation, X is a halogen ion, B′ is tin, and B″ is germanium. Photovoltaic cells (e.g., solar panels) utilizing each of the foregoing perovskite materials are also provided.

In embodiments of the perovskite material, X is a halogen ion. Examples of halogen ions include, but are not limited to, iodide, bromide, and chloride. In certain embodiments of the perovskite material, X is iodide. In certain embodiments of the perovskite material, X is bromide. In certain embodiments of the perovskite material, X is chloride.

In embodiments of the perovskite material, B′ is tin. In embodiments of the perovskite material, B″ is germanium. In certain embodiments, perovskite materials including the combination of tin and germanium has been shown to provide perovskite materials that have acceptable power conversion efficiency, electronic bandgap values, Goldschmit's tolerance factors, and other desirable properties related to photovoltaic cell performance.

In certain embodiments of the perovskite material, A is an organic or inorganic cation. In certain embodiments of the perovskite material, A′ is an inorganic cation. In certain embodiments of the perovskite material, A″ is an organic cation. When utilizing a single cation, denoted “A,” cation A may be any suitable organic or inorganic cation. When utilizing a double cation, denoted “A′” and “A″,” cation A′ may be any suitable inorganic cation, and cation A″ may be any suitable organic cation. Examples of suitable inorganic cations include, but are not limited to, cesium and rubidium. In certain embodiments of the perovskite material, A is cesium. In certain embodiments of the perovskite material, A is rubidium. In certain embodiments of the perovskite material, A′ is cesium. In certain embodiments of the perovskite material, A′ is rubidium.

Examples of suitable organic cations include, but are not limited to, methylammonium (“MA”) and formamidinium (“FA”). In certain embodiments of the perovskite material, A is methylammonium. In certain embodiments of the perovskite material, A is formamidinium. In certain embodiments of the perovskite material, A″ is methylammonium. In certain embodiments of the perovskite material, A″ is formamidinium.

For constructed mixed tin and germanium halide perovskite materials, the Goldschmit's tolerance factor can be used as an empirical indicator to assess structural stability of the perovskite materials. For perovskite materials with general formula ABX₃, Goldschmit's tolerance factor t is defined as

$$t = \frac{{r}_{A} + {r}_{X}}{\sqrt{2} ( {r}_{B} + {r}_{X} )} \qquad Equation 1$$

where r_{A} and r_{B} are the ionic radius of the A- and B-site cations, respectively, and the r_{X} is the ionic radius of anion X. The tolerance factor evaluates empirically whether the A-site cation can fit within the cavities between BX₆ octahedrons. A range of 0.9≤t≤1 is generally viewed as a good fit for perovskite materials, implying likelihood of cubic structures. A range of 0.71≤t≤0.9 is generally implied likely formation of orthorhombic or rhombohedral structure due to the tilting of BX₆ octahedrons. For t≤0.71 or t≥1, there can be alternative structure formation, such as hexagonal structure or NH₄CdCl₃ structure.

However, for the perovskite materials provided herein, the B site is occupied by two different cations (tin and germanium), and the A site can be occupied by two different cations (e.g., an inorganic cation and an organic cation). To establish “t” for the perovskite materials provided herein, the mean ionic radius is adopted for both B site and A site, namely,

$${r}_{B} = \frac{{r}_{{B}^{′}} + {r}_{{B}^{″}}}{2} and {r}_{A} = \frac{{r}_{{A}^{′}} + {r}_{{A}^{″}}}{2} .$$

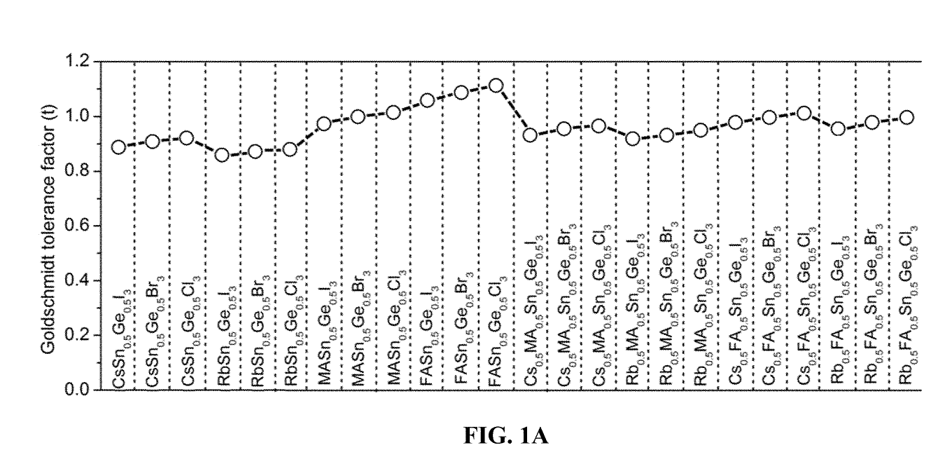

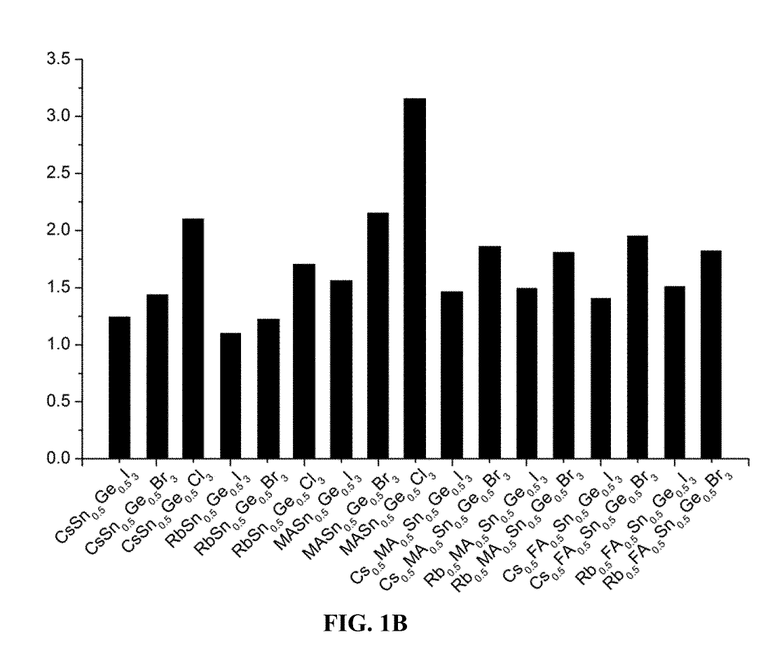

The calculated Goldschmit's tolerance factors are summarized in FIG. 1A. It can be seen that the stable perovskite materials with distorted structures are predicted with their Goldschmit's tolerance factors 0.7<t<0.9, while the predicted perovskite materials with perfect cubic structures are those with their Goldschmit's tolerance factor values of 0.9≤t≤1.0. Considering t factors of perovskite materials within the range of 0.9 to 1 having the formula A′_{0.5}A″_{0.5}B′_{0.5}B″_{0.5}X₃, a 2×2×2 supercell is adopted with respect to cubic unit cell where 4 B′ and 4 B″ occupy 8 B sites, respectively; while 4 A′ and 4 A″ occupy the 8 A sites, respectively. Both A and B sites are alternatively occupied by A′ and A″, and B′ and B″, forming a rock-salt structure.

To assess potential performance of optical absorption materials, electronic bandgap of the materials is an important quantity that should be within an optimal range of 0.9-1.6 eV (to achieve Shockley-Queisser efficiency of approximately 25%). FIG. 1B shows the computed PBE0 bandgaps for 17 perovskite materials. Nine perovskite materials of the 17 shown in FIG. 1B exhibit bandgaps within the optimal region. For these nine perovskite materials with formula AB′_{0.5}B″_{0.5}X₃, the bandgaps increase in the order of iodide<bromide<chloride, with the decrease of ionicity of halogen elements. Lead halide perovskite materials show the same trend. The lead-free chloride perovskite materials exhibit notably wider bandgaps than the iodide and bromide counterparts. Another trend observed is that with increasing the ionic radius for occupying the A site, the bandgap of the corresponding compound increases.

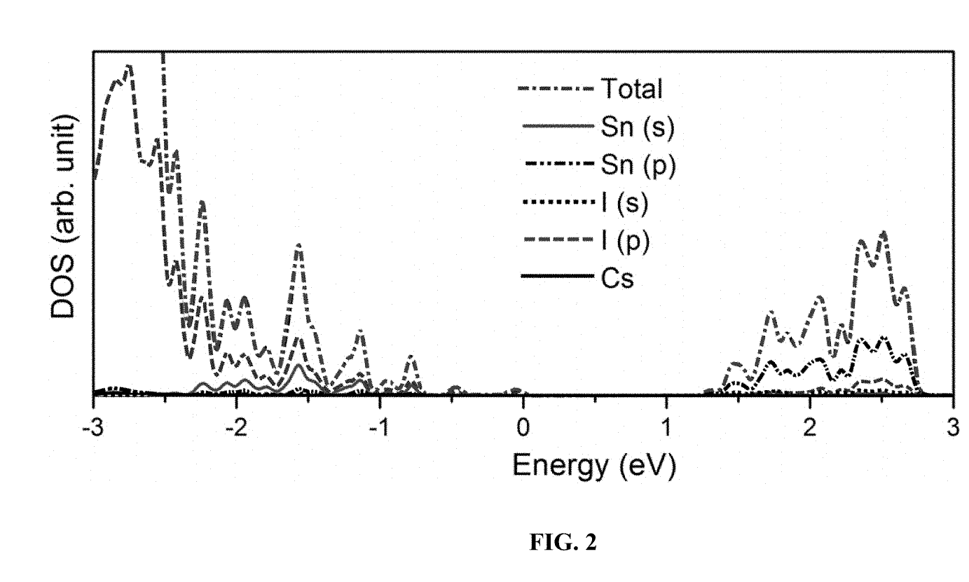

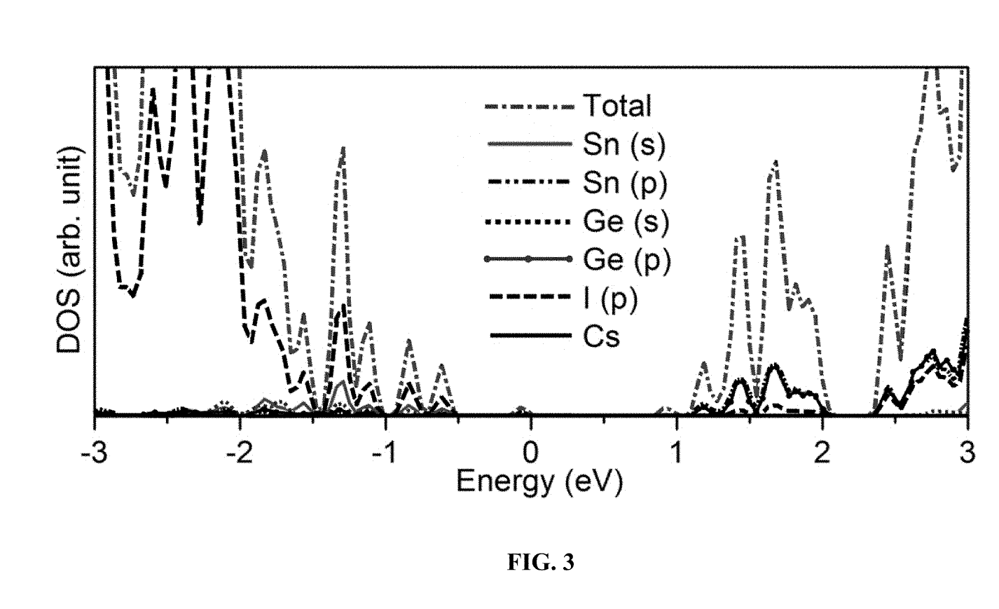

All first-principles computations have been performed based on density-functional theory (“DFT”) methods as implemented in the Vienna ab initio simulation package (“VASP 5.4”). An energy cutoff of 520 eV was employed, and the atomic positions were optimized using a conjugate gradient scheme without any symmetric restrictions until the maximum force on each atom was less than 0.02 eVÅ⁻¹. The electronic structures and the optical properties provided herein have been computed using PBE0 functional with a cutoff energy of 400 eV. The computed PBE0 bandgap (about 1.3 eV) of CsSnI₃ is in good agreement with an experimental value (see FIG. 2). The ion cores are described by using a projector augmented wave (“PAW”) method. Grimme's DFT-D3 correction is adopted to describe the long-range van der Waals interaction. A 3×3×3 k-point grid is used for the mixed tin and germanium halide perovskite materials. For lead halide perovskite materials, spin-orbit coupling (“SOC”) can significantly lower the bandgap. However, it was found that SOC can only slightly reduce the bandgap (by about 0.2 eV) for lead-free halide perovskite materials (see FIG. 3).

For the eight perovskite materials with formula A′_{0.5}A″_{0.5}B′_{0.5}B″_{0.5}X₃, a similar trend can be seen for iodide and bromide. However, there is no clear trend with change of the A-site elements. The complex local structure of materials due to the tilting of octahedron BX₆, induced by different A-site components (e.g., inorganic and organic), results in different electronic structures. To gain insight into the electronic properties of the perovskite materials, the electronic structures of four perovskite materials were computed with bandgaps within the optimal range, namely, CsSn_{0.5}Ge_{0.5}I₃ (1.24 eV), RbSn_{0.5}Ge_{0.5}I₃ (1.15 eV), MASn_{0.5}Ge_{0.5}I₃ (1.58 eV), and Rb_{0.5}FA_{0.5}Sn_{0.5}Ge_{0.5}I₃ (1.50 eV). Possible variation in bandgaps of CsSn_{0.5}Ge_{0.5}I₃ due to some other arrangements of tin and germanium are also estimated. Generally, the variation is less than 0.2 eV.

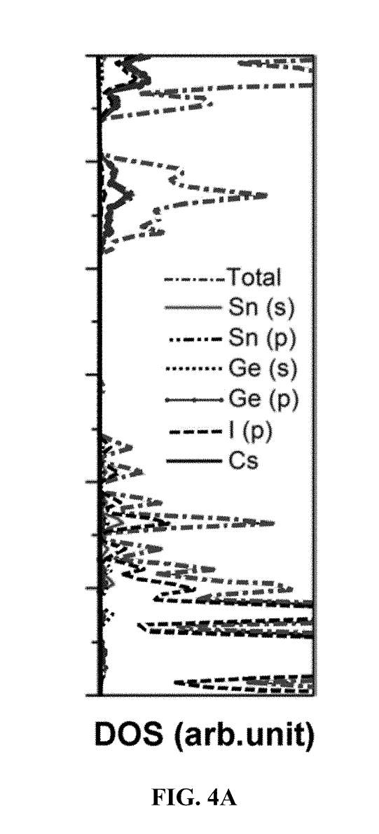

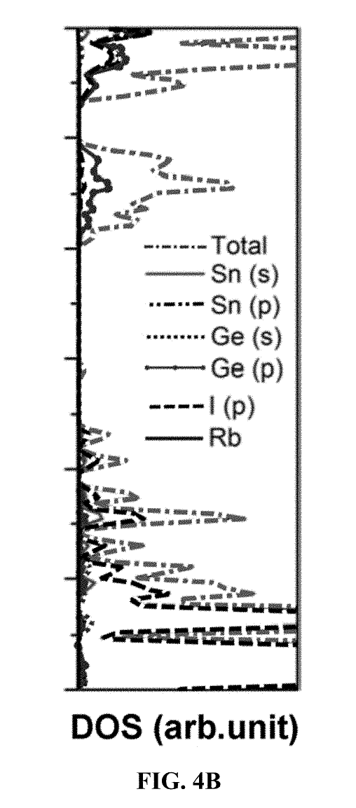

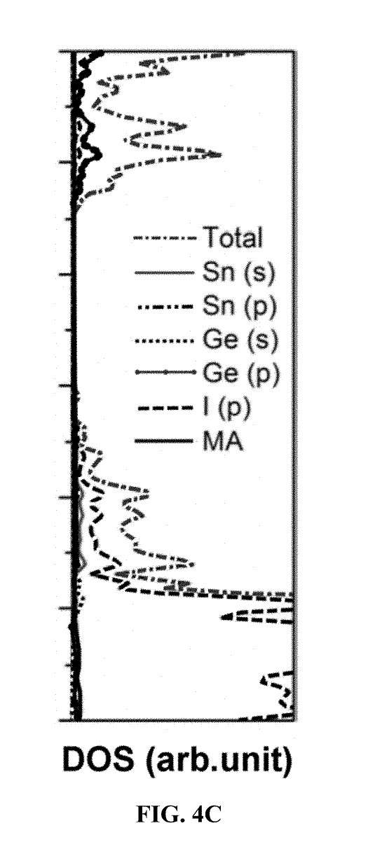

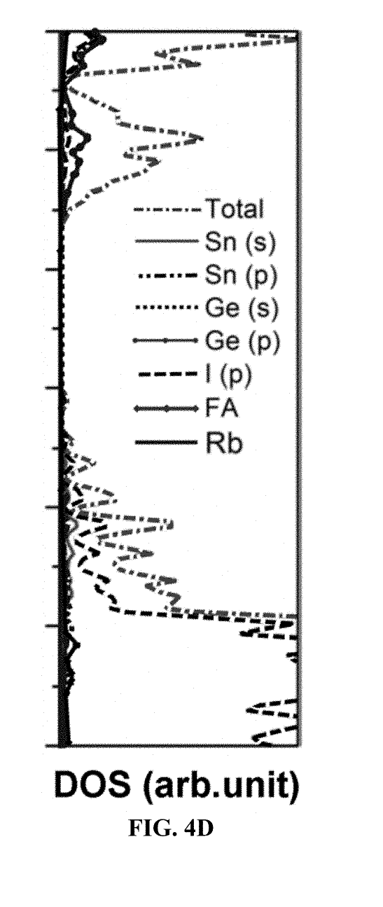

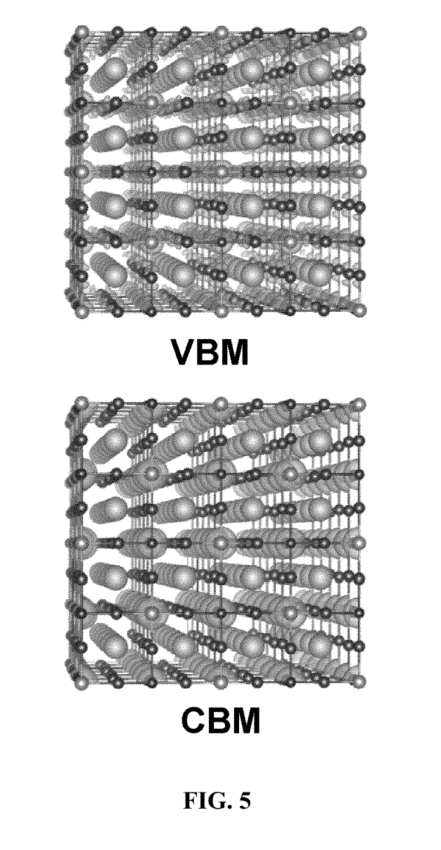

FIGS. 4A-D show computed band structures (based on PBE0 functional) of the identified four perovskites. All the four perovskite materials exhibit direct bandgaps with the valence band maximum (“VBM”) and conduction band minimum (“CBM”) being located at Γ point. The dispersion of the top valence band is larger than that of the bottom conduction band, indicating that the hole has a smaller effective mass. From the projected density of states (“PDOS”) onto the Sn 5s, Sn 5p, Ge 4s, Ge 4p and I 5p orbitals, it can be seen that the upper valence bands are predominantly contributed by Sn 5s, Ge 4s and I 5p orbitals, while the lower conduction bands are predominantly contributed by Sn 5p and Ge 4p orbitals (see FIGS. 4A-D and 5). Similar to the lead halide perovskite material MAPbI₃, the A-site elements cannot directly contribute to the band edges but can indirectly affect the electronic structure via inducing the tilting of octahedrons BX₆ due to different ionic radius of A-site elements. When A sites are occupied by cesium and rubidium, two conduction bands converge at the CBM due to the preserved cubic structure, as in the case of α-CsSnI₃. The flatter band and steeper band are generally referred to as the heavy band and the light band, respectively. In contrast, the two bands are split at the Γ point due to the loss of symmetries of local structures under influence of organic cations.

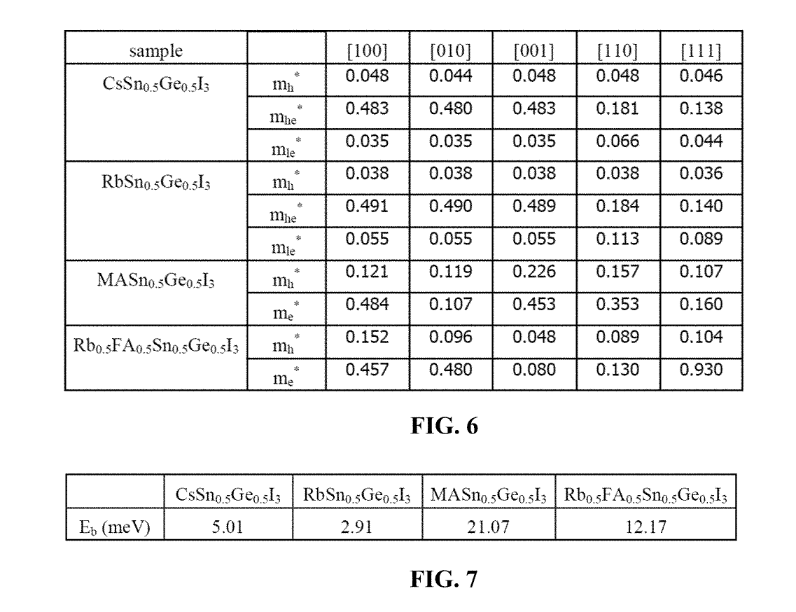

Another factor that can affect performance of photovoltaic cells is carrier mobility, a property related to the effective mass of the carriers. The effective masses of four perovskite materials is calculated by fitting their energy dispersion curves at VBM and CBM to parabolic function along different k directions in the vicinity of the Γ point. FIG. 6 is a table presenting the effective mass tensors corresponding to the [100], [010], [001], [110] and [111] directions, respectively. For holes, calculation of effective mass tensors is straightforward because each band is nondegenerate and parabolic at the Γ point. Low hole mass is found and the mass increases with increasing the radius of A-site cations for AB′_{0.5}B″_{0.5}X₃. If only inorganic cations occupy the A sites, the band dispersions are nearly isotropic due to the symmetries of cubic structures. If organic cations occupy A-sites, their irregular radius can significantly distort the cubic structures, resulting in anisotropic band dispersions. These features are clearly seen from the values of effectives mass corresponding to the [100], [010] and [001] directions, respectively. For CsSn_{0.5}Ge_{0.5}I₃ and RbSn_{0.5}Ge_{0.5}I₃, each has two bands converged at CBM. The obtained electronic effective masses are denoted as the heavy electron (“he”) and light electron (“le”) masses, following the terminology used for the holes in tetrahedral semiconductors. As shown in the table of FIG. 6, the he masses are an order of magnitude higher than hole effective masses while the le masses are comparable to the hole effective masses. For MASn_{0.5}Ge_{0.5}I₃ and Rb_{0.5}FA_{0.5}Sn_{0.5}Ge_{0.5}I₃, most electronic effective masses are higher than the corresponding hole effective masses. As CsSnI₃, the relatively low hole effective masses affect carrier mobility, implying that the materials may be p-type semiconductors.

To evaluate exciton effects, exciton binding energies are calculated using a simple Wannier exciton model. The exciton binding energy is given by

$${E}_{b} = \frac{μ {e}^{4}}{2 {ℏɛ}_{∞}^{2}}$$

(μ: the reduced effective mass,

$$1 \text{/} ( \frac{1}{{m}_{e}} + \frac{1}{{m}_{h}} ) ;$$

ε_{∞}: the high-frequency dielectric constant). The table shown in FIG. 7 shows that four perovskite materials exhibit low exciton binding energy. MASn_{0.5}Ge_{0.5}O₃ has the highest binding energy of 21.07 meV, comparable to that of MAPbI₃ (reported in the range of 19-50 meV), implying fast exciton dissociation for the four perovskite materials listed in FIG. 7. The calculated exciton binding energies exhibit the same trend as the effective masses, i.e., they decrease with decreasing radius of A-site cations.

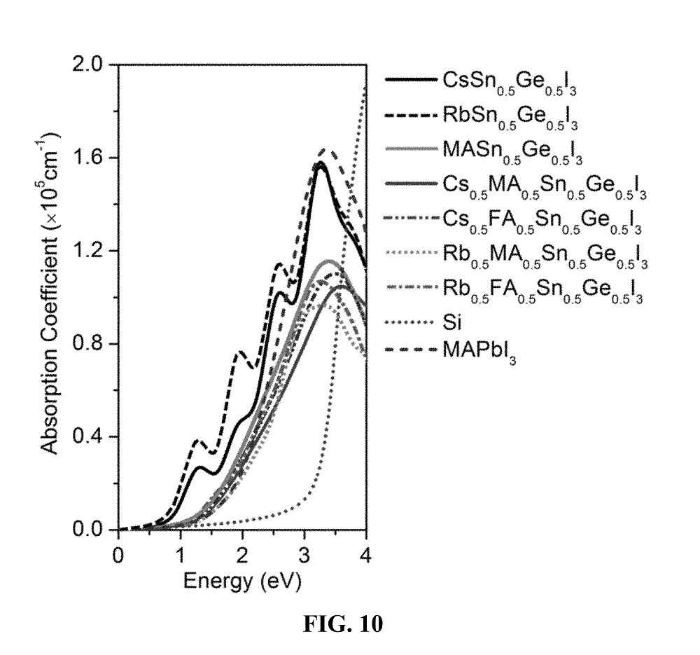

In addition to bandgap and carrier mobility, optical absorption is another property used to assess performance of absorber (e.g., perovskite) materials. FIG. 10 shows the computed absorption spectra of certain perovskite materials provided herein. Computed absorption spectra for prototypical high-efficiency photovoltaic materials, silicon and MAPbI₃, are also included for comparison. The absorption coefficient is given by

$$α ( ) = {\frac{\sqrt{2} e}{ℏ c} [ {( {ɛ}_{1}^{2} + {ɛ}_{2}^{2} )}^{\frac{1}{2}} - {ɛ}_{1} ]}^{\frac{1}{2}} ,$$

wherein ε₁ and ε₂ are real and imaginary part of dielectric function, respectively. According to the AM 1.5 solar spectrum, 98% of the solar power reaching to the earth's surface is contributed by the photons below 3.4 eV. CsSn_{0.5}Ge_{0.5}I₃ and RbSn_{0.5}Ge_{0.5}I₃ exhibit stronger absorption than other predicted materials and their absorption spectra are close to that of MAPbI₃. Moreover, both materials display moderate absorption in the infrared region. These favorable absorption properties show that each of CsSn_{0.5}Ge_{0.5}I₃ and RbSn_{0.5}Ge_{0.5}I₃ should be good photovoltaic absorber materials. For other perovskite materials provided herein, although their absorption intensities may be slightly lower, some of these perovskite materials possess suitable bandgaps and show reasonably good optical absorption behavior.

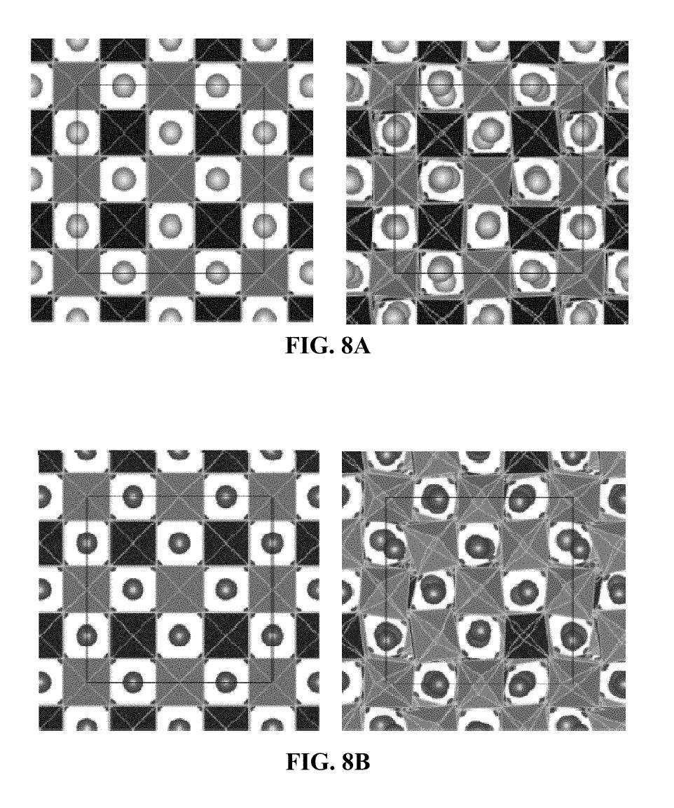

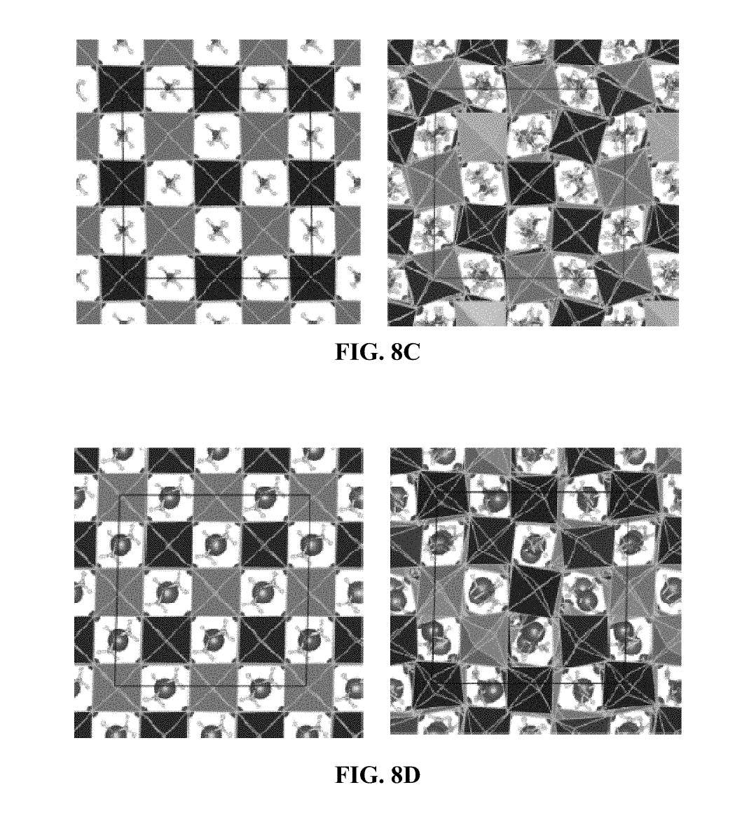

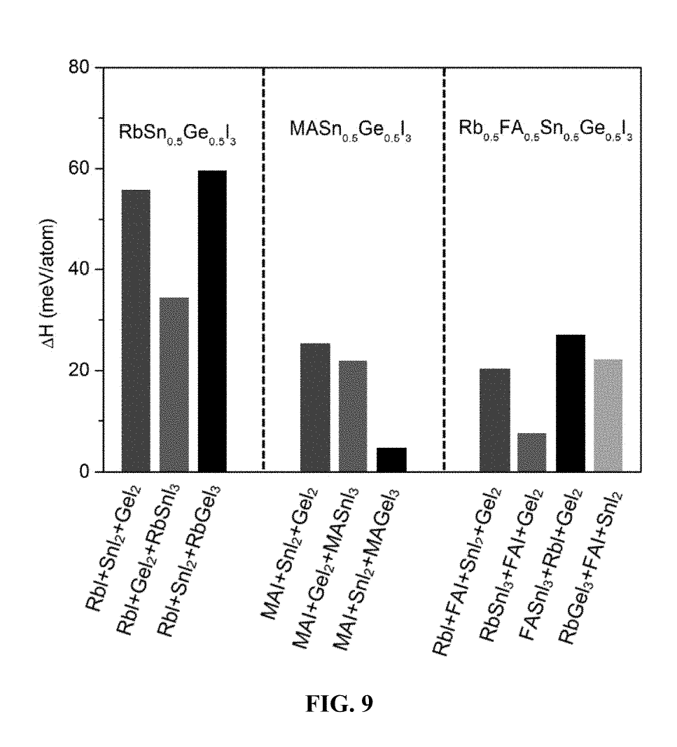

Thermal stability of perovskite materials is another property of interest. Thermal stability was examined using ab initio molecular dynamics (“AIMD”) simulations (see FIGS. 8A-D, with 8A depicting CsSn_{0.5}Ge_{0.5}I₃, 8B depicting RbSn_{0.5}Ge_{0.5}I₃, 8C depicting MASn_{0.5}Ge_{0.5}I₃, and 8D depicting Rb_{0.5}FA_{0.5}Sn_{0.5}Ge_{0.5}I₃). The predicted materials are still intact after 5 ps simulations with the temperature of the system being controlled at 300 K. Decomposition energies are also calculated with respect to possible decomposition pathways. For example, if a compound ASn_{0.5}Ge_{0.5}I₃ decomposes into corresponding binary materials, the decomposition enthalpy is defined as ΔH=E[AI]+0.5E[SnI₂]+0.5E[GeI₂]−E[ASn_{0.5}Ge_{0.5}I₃]. A positive value of ΔH means energy is released for the formation of ASn_{0.5}Ge_{0.5}I₃, demonstrating that the compound is energetically favorable. FIG. 9 shows the decomposition enthalpy ΔH of different decomposition pathways for RbSn_{0.5}Ge_{0.5}I₃, MASn_{0.5}Ge_{0.5}I₃, and Rb_{0.5}FA_{0.5}Sn_{0.5}Ge_{0.5}I₃. Note that RbSn_{0.5}Ge_{0.5}I₃ gives a relatively large positive value of ΔH, while MASn_{0.5}Ge_{0.5}I₃ and Rb_{0.5}FA_{0.5}Sn_{0.5}Ge_{0.5}I₃ yield relatively smaller positive values of ΔH. While not wishing to be bound by theory, organic cations are believed to interact relatively weakly with the inorganic framework, which is believed to cause the variation in ΔH previously described.

To make the perovskite materials described herein, appropriate amounts of tin-halide salt, germanium-halide salt, and inorganic- and/or organic-halide salt are heated under vacuum at relatively high temperature (e.g., about 430° C.) until reaction completion, resulting in the perovskite material. In certain embodiments, the mixed tin and germanium halide perovskite materials utilize one of two previously reported methods for synthesis of CsSnI₃ and MAPb_{0.5}Sn_{0.5}I₃. For example, synthesis of RbSn_{0.5}Ge_{0.5}I₃ may be proceeded by placing an appropriate amount of SnI₂, GeI₂ and RbI in an appropriate container, e.g., a pyrex tube. The tube is evacuated and sealed. The evacuated tube is then heated to high temperature (e.g., about 430° C.) to produce CsSn_{0.5}Ge_{0.5}I₃. The synthesis of MASn_{0.5}Ge_{0.5}I₃ and Rb_{0.5}FA_{0.5}Sn_{0.5}Ge_{0.5}I₃ may be proceeded using solution synthesis as previously reported for mixed lead halide perovskite materials.

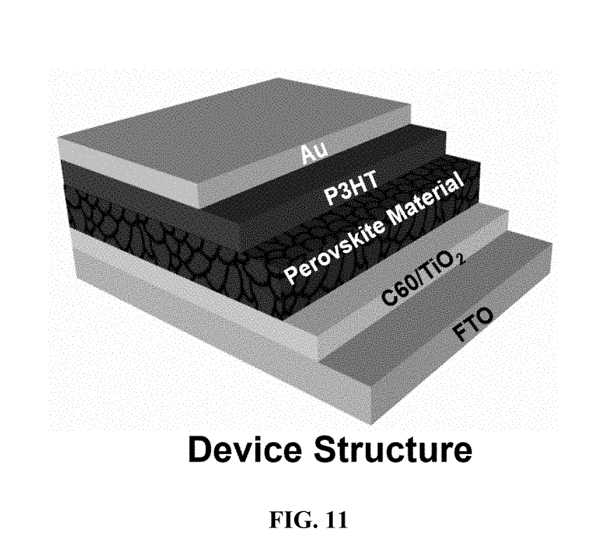

The perovskite materials provided herein may be utilized in photovoltaic cells (e.g., solar panels). Photovoltaic cells can be used to capture and convert light energy into electricity. In certain embodiments, a photovoltaic cell can be fabricated using a perovskite material as described herein. Onto a cleaned substrate comprising, e.g., etched fluorine-doped tin oxide coated (“FTO”) glass, a compact titanium dioxide (“TiO₂”) electron-transporting layer is applied. The TiO₂ electron-transporting layer may be applied, e.g., via spraying a diluted titanium diisopropoxide bis(acetylacetonate) (“TAA”) solution in ethanol (0.2 ml of TAA in 6 ml of anhydrous ethanol) at an elevated temperature (e.g., about 450° C.). A thin film of perovskite material is deposited according to procedures known in the art and then flash evaporated. After evaporation, the intermediate photovoltaic cell comprising the perovskite material was cooled to room temperature. A hole-transporting material (“HTM”) solution for forming an HTM layer can be prepared, e.g., by dissolving 10 mg of poly(3-hexylthiophene-2,5-diyl) (“P3HT”) in 1 mL of toluene and deposited onto the thin film of perovskite material, e.g., by spin-coating the HTM solution at 3000 rpm for 15 s. An electrode is deposited onto the HTM layer according to procedures known to those in the art, e.g., by thermal evaporation. In certain embodiments of the photovoltaic cell, the electrode is a gold electrode. FIG. 11 shows an illustration of a photovoltaic cell fabricated according to this procedure.

In conclusion, a series of lead-free mixed tin and germanium halide perovskite materials for photovoltaic applications are provided. Nine materials are identified to possess desirable bandgaps. Among them, CsSn_{0.5}Ge_{0.5}I₃ exhibits comparable absorption spectrum of sun light as the well-known prototype MAPbI₃. Meanwhile, small effective masses and low exciton binding energies are expected for these materials, indicating that the materials are extremely promising as a photovoltaic absorber. Moreover, the bandgap can be tuned over a wide range (e.g., about 0.9-3.15 eV) with respect to the composition change involved in the mixing element strategy. The mixed tin and germanium halide perovskite materials advantageously serve as a highly efficient absorption material, while addressing some known challenging issues inherent in the lead halide perovskite photovoltaic cells.

### EXAMPLES

The following examples further illustrate the invention but should not be construed as in any way limiting its scope.

### Example 1

CsSn_{0.5}Ge_{0.5}I₃ perovskite material was synthesized by solid-state reaction in evacuated quartz tubes. Stoichiometric amounts of CsI, GeI₂, SnI₂ (available from Sigma Aldrich, USA) were placed in quartz tubes and evacuated to about 1×10⁻⁶ Torr and sealed using an oxy-methane torch. The evacuated tube was heated to 430° C. at 10° C./min and held for 72 hours at 430° C. before slowly cooling the tube to room temperature at 10° C./min. The sealed tube was opened in a glove box filled with nitrogen gas for further characterization/testing.

A thin film of CsSn_{0.5}Ge_{0.5}I₃ perovskite material was prepared by flash evaporation as is known in the art of the as-synthesized CsSn_{0.5}Ge_{0.5}I₃ powders directly.

### Example 2

A photovoltaic cell was fabricated using the CsSn_{0.5}Ge_{0.5}I₃ perovskite material synthesized in Example 1. Chemically etched FTO glass (available from Nippon Sheet Glass) was cleaned with detergent solution, acetone, and isopropanol. To form a 20 to 25 nm compact titanium dioxide (“TiO₂”) electron-transporting layer, diluted titanium diisopropoxide bis(acetylacetonate) (“TAA”) solution (available from Sigma-Aldrich) in ethanol (0.2 ml of TAA in 6 ml of anhydrous ethanol) was sprayed at 450° C. A thin film of CsSn_{0.5}Ge_{0.5}I₃ from Example 1 was then deposited. After evaporation, the prepared CsSn_{0.5}Ge_{0.5}I₃ was cooled to room temperature in the vacuum chamber. A hole-transporting material (“HTM”) solution for forming an HTM layer was prepared by dissolving 10 mg of poly(3-hexylthiophene-2,5-diyl) (“P3HT”) in 1 mL of toluene. An HTM layer was formed on the thin film of CsSn_{0.5}Ge_{0.5}I₃ by spin-coating the HTM solution at 3000 rpm for 15 s, and followed by the deposition of the 80 nm thick gold electrode by thermal evaporation. FIG. 11 shows an illustration of a photovoltaic cell fabricated according to this example, wherein the perovskite material, once evaporated, is CsSn_{0.5}Ge_{0.5}I₃.

### REFERENCES

(1) Green, M. A.; Ho-Baillie, A.; Snaith, H. J.; Nat. Photonics 2014, 8, 506-514.
(2) Yablonovitch, E.; Science 2016, 351, 1401.
(3) National Renewable Energy Laboratory; Best Research-Cell Efficiencies; https://www.nrel.gov/pv/assets/images/efficiency-chart.png (last visited Feb. 22, 2018).
(4) Lee, J. W.; Seol, D. J.; Cho, A. N.; Park, N. G.; Adv. Mater. 2014, 26, 4991-4998.
(5) Pellet, N.; Gao, P.; Gregori, G.; Yang, T. Y.; Nazeeruddin, M. K.; Maier, J.; Gratzel, M.; Angew. Chem., Int. Ed. 2014, 53, 3151-3157.
(6) Yang, W. S.; Noh, J. H.; Jeon, N. J.; Kim, Y. C.; Ryu, S.; Seo, J.; Seok, S. Il.; Science 2015, 348, 1234-1237.
(7) Koh, T. M.; Fu, K.; Fang, Y.; Chen, S.; Sum, T. C.; Mathews, N.; Mhaisalkar, S. G.; Boix, P. P.; Baikie, T.; J. Phys. Chem. C 2014, 118, 16458-16462.
(8) Hu, M.; Liu, L.; Mei, A.; Yang, Y.; Liu, T.; Han, H.; J. Mater. Chem. A 2014, 2, 17115-17121.
(9) Binek, A.; Hanusch, F. C.; Docampo, P.; Bein, T.; J. Phys. Chem. Lett. 2015, 6, 1249-1253.
(10) Hoke, E. T.; Slotcavage, D. J.; Dohner, E. R.; Bowring, A. R.; Karunadasa, H. I.; McGehee, M. D.; Chem. Sci. 2015, 6, 613-617.
(11) Eperon, G. E.; Stranks, S. D.; Menelaou, C.; Johnston, M. B.; Herz, L. M.; Snaith, H.; J. Energy Environ. Sci. 2014, 7, 982.
(12) Jacobsson, T. J.; Correa-Baena, J. P.; Pazoki, M.; Saliba, M.; Schenk, K.; Grätzel, M.; Hagfeldt, A.; Energy Environ. Sci. 2016, 9, 1706-1724.
(13) Eperon, G. E.; Leijtens, T.; Bush, K. A.; Prasanna, R.; Green, T.; Wang, J. T.-W.; McMeekin, D. P.; Volonakis, G.; Milot, R. L.; May, R.; Science 2016, 354, 861-865.
(14) McMeekin, D. P.; Sadoughi, G.; Rehman, W.; Eperon, G. E.; Saliba, M.; Horantner, M. T.; Haghighirad, A.; Sakai, N.; Korte, L.; Rech, B.; Johnston, M. B.; Herz, L. M.; Snaith, H. J.; Science 2016, 351, 151-155.
(15) (a) Yokoyama, T.; Cao, D. H.; Stoumpos, C. C.; Song, T.; Sato, Y.; Aramaki, S.; Kanatzidis, M. G.; J. Phys. Chem. Lett. 2016, 7, 776-782. (b) Ju, M.-G.; Dai, J.; Ma, L.; Zeng, X. C.; Adv. Energy Mater. 2017, 1700216.
(16) Hao, F.; Stoumpos, C. C.; Cao, D. H.; Chang, R. P. H.; Kanatzidis, M. G.; Nat. Photonics 2014, 8, 489-494.
(17) Noel, N. K.; Stranks, S. D.; Abate, A.; Wehrenfennig, C.; Guarnera, S.; Haghighirad, A.-A.; Sadhanala, A.; Eperon, G. E.; Pathak, S. K.; Johnston, M. B.; Petrozza, A.; Herz, L. M.; Snaith, H. J.; Energy Environ. Sci. 2014, 7, 3061-3068.
(18) Kumar, M. H.; Dharani, S.; Leong, W. L.; Boix, P. P.; Prabhakar, R. R.; Baikie, T.; Shi, C.; Ding, H.; Ramesh, R.; Asta, M.; Graetzel, M.; Mhaisalkar, S. G.; Mathews, N.; Adv. Mater. 2014, 26, 7122-7127.
(19) Wang, N.; Zhou, Y.; Ju, M. G.; Garces, H. F.; Ding, T.; Pang, S.; Zeng, X. C.; Padture, N. P.; Sun, X. W.; Adv. Energy Mater. 2016, 6, 1601130.
(20) Marshall, K. P.; Walker, M.; Walton, R. I.; Hatton, R. A.; Nat. Energy 2016, 1, 16178.
(21) Kresse, G.; Furthmuller, J.; Comput. Mater. Sci. 1996, 6, 15-50.
(22) Paier, J.; Hirschl, R.; Marsman, M.; Kresse, G.; J. Chem. Phys. 2005, 122, 234102.
(23) Chung, I.; Song, J.-H.; Im, J.; Androulakis, J.; Malliakas, C. D.; Li, H.; Freeman, A. J.; Kenney, J. T.; Kanatzidis, M. G.; J. Am. Chem. Soc. 2012, 134, 8579-8587.
(24) Gajdos, M.; Hummer, K.; Kresse, G.; Furthmuller, J.; Bechstedt, F.; Phys. Rev. B: Condens. Matter Mater. Phys. 2006, 73, 45112.
(25) Grimme, S.; Antony, J.; Ehrlich, S.; Krieg, H.; J. Chem. Phys. 2010, 132, 154104.
(26) Zhang, M.; Lyu, M.; Yun, J. H.; Noon, M.; Zhou, X.; Cooling, N. A.; Wang, Q.; Yu, H.; Dastoor, P. C.; Wang, L.; Nano Res. 2016, 9, 1570-1577.
(27) Stoumpos, C. C.; Frazer, L.; Clark, D. J.; Kim, Y. S.; Rhim, S. H.; Freeman, A. J.; Ketterson, J. B.; Jang, J. I.; Kanatzidis, M. G.; J. Am. Chem. Soc. 2015, 137, 6804-6819.
(28) Huang, L.-Y.; Lambrecht, W. R. L.; Phys. Rev. B 2013, 88, 165203-165214.
(29) Huang, L.-Y.; Lambrecht, W. R. L.; Phys. Rev. B: Condens. Matter Mater. Phys. 2016, 94, 115202.
(30) Stoumpos, C. C.; Kanatzidis, M. G.; Acc. Chem. Res. 2015, 48, 2791-2802.
(31) Shi, C.; Yu, C. H.; Zhang, W.; Angew. Chem., Int. Ed. 2016, 55, 5798-5802.
(32) Kieslich, G.; Sun, S.; Cheetham, A.; Chem. Sci. 2015, 6, 3430-3433.
(33) Travis, W.; Glover, E. N. K.; Bronstein, H.; Scanlon, D. O.; Palgrave, R. G.; Chem. Sci. 2016, 7, 4548-4556.
(34) Li, Z.; Yang, M.; Park, J. S.; Wei, S. H.; Berry, J. J.; Zhu, K.; Chem. Mater. 2016, 28, 284-292.
(35) Volonakis, G.; Filip, M. R.; Haghighirad, A. A.; Sakai, N.; Wenger, B.; Snaith, H. J.; Giustino, F.; J. Phys. Chem. Lett. 2016, 7, 1254-1259.
(36) Ma, L.; Dai, J.; Zeng, X. C.; Adv. Energy Mater. 2017, 7, 1601731.
(37) Protesescu, L.; Yakunin, S.; Bodnarchuk, M. I.; Krieg, F.; Caputo, R.; Hendon, C. H.; Yang, R. X.; Walsh, A.; Kovalenko, M. V.; Nano Lett. 2015, 15, 3692-3696.
(38) Sum, T. C.; Mathews, N.; Energy Environ. Sci. 2014, 7, 2518-2534.
(39) Mosconi, E.; Umari, P.; De Angelis, F.; Phys. Chem. Chem. Phys. 2016, 18, 27158-27164.
(40) Mosconi, E.; Umari, P.; De Angelis, F.; J. Mater. Chem. A 2015, 3, 9208-9215.
(41) Umari, P.; Mosconi, E.; De Angelis, F.; Sci. Rep. 2015, 4, 4467.
(42) Even, J.; Pedesseau, L.; Jancu, J.; Katan, C.; J. Phys. Chem. Lett. 2013, 4, 2999-3005.
(43) Zhao, X.; Yang, J.; Fu, Y.; Yang, D.; Xu, Q.; Yu, L.; Wei, S.-H.; Zhang, L.; J. Am. Chem. Soc. 2017, 139, 2630-2638.
(44) Leguy, A. M. A.; Hu, Y.; Campoy-Quiles, M.; Alonso, M. I.; Weber, O. J.; Azarhoosh, P.; Van Schilfgaarde, M.; Weller, M. T.; Bein, T.; Nelson, J.; et al.; Chem. Mater. 2015, 27, 3397-3407.
(45) Henkelman, G.; Uberuaga, B. P.; Jonsson, H.; J. Chem. Phys. 2000, 113, 9901-9904.
(46) Koocher, N. Z.; Saldana-Greco, D.; Wang, F.; Liu, S.; Rappe, A. M.; J. Phys. Chem. Lett. 2015, 6, 4371-4378.
(47) Mosconi, E.; Azpiroz, J. M.; De Angelis, F.; Chem. Mater. 2015, 27, 4885-4892.
(48) Ogomi, Y.; Morita, A.; Tsukamoto, S.; Saitho, T.; Fujikawa, N.; Shen, Q.; Toyoda, T.; Yoshino, K.; Pandey, S. S.; Ma, T.; et al.; J. Phys. Chem. Lett. 2014, 5, 1004-1011.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A perovskite material having the formula AB′_{0.5}B″_{0.5}X₃, wherein A is an organic or inorganic cation, X is a halogen ion, B′ is tin, and B″ is germanium.

2. The perovskite material of claim 1, wherein A is cesium.

3. The perovskite material of claim 2, wherein X is iodide or bromide.

4. The perovskite material of claim 1, wherein A is rubidium.

5. The perovskite material of claim 4, wherein X is iodide or bromide.

6. The perovskite material of claim 1, wherein A is methylammonium.

7. The perovskite material of claim 1, wherein A is formamidinium.

8. The perovskite material of claim 1, wherein X is iodide.

9. The perovskite material of claim 1, wherein X is bromide.

10. A photovoltaic cell comprising a substrate, a blocking layer, an optical absorption material comprising the perovskite material of claim 1, a hole-transporting material, and an electrode.

11. A perovskite material having the formula A′_{0.5}A″_{0.5}B′_{0.5}B″_{0.5}X₃, wherein A′ is an inorganic cation and A″ is an organic cation, X is a halogen ion, B′ is tin, and B″ is germanium.

12. The perovskite material of claim 11, wherein A′ is cesium and A″ is methylammonium.

13. The perovskite material of claim 12, wherein X is iodide.

14. The perovskite material of claim 11, wherein A′ is rubidium, and A″ is methylammonium.

15. The perovskite material of claim 14, wherein X is iodide.

16. The perovskite material of claim 11, wherein A′ is cesium and A″ is formamidinium.

17. The perovskite material of claim 16, wherein X is iodide.

18. The perovskite material of claim 11, wherein A′ is rubidium and A″ is formamidinium.

19. The perovskite material of claim 18, wherein X is iodide.

20. The perovskite material of claim 11, wherein X is iodide.

21. A photovoltaic cell comprising a substrate, an electron-transporting layer, an optical absorption material comprising the perovskite material of claim 11, a hole-transporting material, and an electrode.
